(19) United States
(12) Patent Application Publication
(10) Pub. No.: US 2005/0224799 A1
(43) Pub. Date: Oct. 13, 2005

(54) Semiconductor device and method for fabricating the same

(75) Inventors: Shinichi Yamamoto, Osaka (JP); Nishio Mikio, Osaka (JP); Tetsuo Kawakita, Kyoto (JP); Hiroshi Tsutsu, Osaka (JP)

Correspondence Address: McDermott Will & Emery, 600 13th Street, N W, Washington, DC, 20005-3096, US

(73) Assignee: MATSUSHITA ELECTRIC INDUSTRIAL CO., LTD., Osaka (JP)

(21) Appl. No.: 10/503,488

(22) PCT Filed: Feb. 7, 2002
(86) PCT No.: PCT/JP02/01004

§ 371 Date: Aug. 5, 2004

(51) Int. Cl. H01L 29/786; H01L 21/84

(52) U.S. Cl. 257/66; 257/349; 438/166; 438/163

(57) ABSTRACT

A semiconductor device provided with a thin-film transistor comprising a polycrystalline semiconductor thin film (2) formed on an insulating substrate (100). The semiconductor device comprises a channel region (80), a source region (91), and a drain region (92), each disposed on both sides of the channel region (80) in the semiconductor thin film (100). The channel region (90) comprises both a first conductive impurity and a second conductive impurity, the conductive type of the second conductive impurity being opposite the conductive type of the first conductive impurity, and is structured by layering a first layer in which the first conductive impurity and the second conductive impurity are canceled and a second layer in which either of the first conductive impurity or the second conductive impurity is dominant, wherein a gate electrode (4) is formed so as to face the first layer (2a) via an insulating film (3). The source region (91) and the drain region (92) have a conductive type that is opposite the conductive type that is dominant in the second layer (2b). This structure reduces OFF-current and makes it easy to control threshold voltage.

### TECHNICAL FIELD

The present invention relates to a semiconductor device and its fabrication method, especially to a semiconductor device having a thin-film transistor in which a source region, a channel region and a drain region are formed in a semiconductor thin film composed of polycrystalline silicon, and a fabrication method thereof.

### BACKGROUND ART

Currently, semiconductor devices, including liquid crystal displays, are being actively developed. Thin-film transistors (TFTs) formed in conventional semiconductor devices have a common structure wherein an active layer is composed of amorphous silicon. Because amorphous silicon TFTs have low carrier mobility and do not have sufficiently good operating characteristics, polycrystalline silicon TFTs are recently attracting attention. Polycrystalline silicon TFTs offer excellent operating characteristics compared with amorphous silicon TFTs, and can be used not only as a pixel switching device but also as a peripheral drive circuit device. In particular, the polycrystalline silicon TFT can be suitably used in a large-screen, high-resolution liquid crystal display with an internal drive circuit. Fabrication processes for polycrystalline silicon TFTs can be roughly divided into high-temperature processes in which thermal treatment is conducted at 1000° C. or more, and low-temperature processes in which the highest temperature is held to 600° C. or less. Currently, a low-temperature process wherein glass, which is advantageous in respect of cost, can be used as an insulating substrate is the mainstream process. An example of a polycrystalline silicon TFT in a conventional semiconductor device is shown in FIG. 12.

As shown in this figure, a buffer layer 130 is formed on an insulating substrate 120, which is composed of glass, and a semiconductor thin film 110, which is composed of polycrystalline silicon, is formed on the buffer layer 130. The semiconductor thin film 110 comprises a channel region 140, a source/drain region 142, and an LDD (lightly doped drain) region 141, and is structured so that the electric field concentration at the drain end can be alleviated to some extent by the LDD region 141.

The semiconductor thin film 110 is covered with a gate insulator layer 115, and a gate film 144 is formed above the channel region 140 via the gate insulator layer 115. The gate film 144 is covered with an interlayer insulation layer 125, and the source/drain region 142 is connected to the source electrode 147 and the drain electrode 148 via contact holes formed in the gate insulator layer 115 and the layer insulation layer 125. Furthermore, the gate film 144 is connected to a gate electrode 145 via a contact hole formed in the interlayer insulation layer 125.

Typical characteristics of polycrystalline silicon TFTs having such a configuration are shown in FIG. 13. This figure is a graph showing the relationship between gate voltage V_{GS} and drain current I_{D} when drain voltage V_{DS} is 4 V. Drain current I_{D} becomes weakest in the vicinity wherein gate voltage V_{GS} is 0 V, and drain current I_{D} increases with an increase in gate voltage V_{GS}. Because an increase in drain current I_{D} in the region where gate voltage V_{GS} is positive indicates a change of the transistor from its OFF-state to its On-state, the larger the increase ratio of the current, the better. For example, when a polycrystalline silicon TFT is used in a liquid crystal display, since the display of the liquid crystal depends on the electric potential of a capacitor, a sufficient current (ON-state current) has to be supplied to the TFT so that data can be written in a short time. Since the carrier mobility in a semiconductor thin film is quite high in a polycrystalline silicon TFT, there is no specific problem in supplying sufficient ON-state current. However, in a polycrystalline silicon TFT, a high-density trap exists in the crystal grain boundary of the semiconductor thin film, and carriers moves through this trap. Therefore, drain current I_{D} increases with an increase in the absolute value of gate voltage V_{GS} even in regions where gate voltage V_{GS} is negative. This phenomenon indicates that the OFF-state current, that is, leakage current in the OFF state, exhibits gate-voltage dependence. This characteristic is not preferable in a transistor. Moreover, it is also necessary to further reduce the OFF-state current itself. For example, since a polycrystalline silicon TFT for an active matrix type liquid crystal display is used under gate reverse bias, data retention characteristics suffer when the OFF-state current rises. That is, although the data written in the capacitor must be retained for a much longer time than that required for writing, since the electrostatic capacity of the capacitor is small, the electric potential of the drain (that is, the electric potential of the capacitor) rapidly approaches that of the source due to the OFF-state current that is generated when the TFT is in the OFF state, and the written data are not correctly retained. The problems caused by an increase in the OFF-state current arise not only in liquid crystal displays but also in other semiconductor devices. For example, this increases the static current in standard logic circuits, and causes malfunctions in memory circuits.

It is also known that impurities introduced into the channel region 140 to form a p− region reduce the OFF-state current. However, while the concentration of the implanted impurity must be relatively low, it is difficult to control the concentration in conventional low-temperature processes, and therefore implementation of such a technique was difficult. Moreover, threshold voltage Vₜₕ is not controlled satisfactorily for the same reason, and, sometimes, the semiconductor thin film is contaminated with an impurity from the beginning, making the operating characteristics of the TFT nonuniform over a large-area insulating substrate. For example, in the case of a liquid crystal display, if threshold voltage Vₜₕ moves to the depression side, the OFF-state current will increase, causing luminescent spot defects in the pixels.

### DISCLOSURE OF THE INVENTION

The present invention aims to provide a semiconductor device that reduces OFF current and easily controls threshold voltage, and a method for fabricating such a semiconductor device.

A semiconductor device for accomplishing the above object comprising:
a thin-film transistor comprising a polycrystalline semiconductor thin film formed on an insulating substrate;
a channel region in the semiconductor thin film; and
a source region and a drain region each disposed on a different end of the channel region;
the channel region comprising both a first conductive impurity and a second conductive impurity, the second conductive impurity being opposite to the first conductive impurity, and structured by layering a first layer in which the first conductive impurity and the second conductive impurity are canceled and a second layer in which either the first conductive impurity or the second conductive impurity is dominant;
a gate electrode being formed so as to face the first layer via an insulating film; and
the source region and the drain region being formed of the conductive impurity opposite to the one that is dominant in the second layer.

Such a semiconductor device can reduce leak current in the OFF state because the conductive type of the source region and drain region disposed on both sides of the second layer is opposite to that of the second conductive layer.

The first layer is an intrinsic-like layer because the first conductive impurity and the second conductive impurity are canceled by each other. Because the gate electrode is formed so as to face the first layer, the threshold voltage can be easily controlled.

The gate electrode may be formed on the semiconductor thin film, or alternatively may be formed between the insulating substrate and the semiconductor thin film.

It is preferable that both the source region and the drain region comprise a high-concentration impurity region and a low-concentration impurity region, the low-concentration impurity region being disposed between the channel region and the high-concentration impurity region and having an impurity concentration that is lower than that of the high-concentration impurity region.

The difference in concentration between the first conductive impurity and the second conductive impurity in the first layer may be defined as less than 5×10¹⁶/cm³. It is preferable that the thickness of the first layer defined as above be not less than 1 nm and not more than 50% of the total thickness of the channel region.

The difference in the concentrations of the two types of impurities in the first layer has a correlation with the sheet resistance of the surface such that when the difference in the concentrations of the impurities becomes smaller, the sheet resistance becomes greater. Specifically, when the first layer is defined as above, the sheet resistance of the surface becomes greater than 1×10⁹ Ω/□. There is no upper limit to the sheet resistance; however, the upper limit may be, for example, approximately 1×10¹² Ω/□.

It is preferable that the source region and the drain region be n type, and that the second layer be a p type layer in which p type is dominant. The insulating substrate may be formed of glass and the semiconductor thin film may be formed directly on the insulating substrate.

The object of the present invention can be achieved by a method for fabricating a semiconductor device provided with a thin-film transistor comprising a semiconductor thin film comprising:
a first impurity introduction step of forming, on an insulating substrate, a semiconductor thin film to which either a first conductive impurity or a second conductive impurity is introduced into an insulating substrate, the second conductive impurity being the opposite conductive type to that of the first conductive impurity;
a polycrystallization step of polycrystallizing the semiconductor thin film by subjecting it to intensive light or laser light;
a second impurity introduction step of forming a channel region having a layered structure of a first layer in which the first conductive impurity and the second conductive impurity are canceled and a second layer in which either the first conductive impurity or the second conductive impurity is dominant by introducing an impurity whose conductive type is opposite to that of the impurity introduced in the first impurity introduction step into the polycrystalline semiconductor thin film;
a gate electrode formation step of forming a gate electrode on the first layer via the insulating film; and
a third impurity introduction step of forming a source region and a drain region in which the conductive type of the introduced impurity becomes dominant by introducing an impurity of a conductive type that is opposite to that of the second layer by using the gate electrode as a mask.

The third impurity introduction step comprises:
a low-concentration impurity region formation step of forming a low-concentration impurity region in which the conductive type of the introduced impurity becomes dominant by introducing an impurity of a conductive type that is opposite to that of the second layer by using the gate electrode as a mask, and forming a channel region below the gate electrode; and
a high-concentration impurity region formation step of covering part of the region adjacent to the channel region, and forming high-concentration impurity regions on both sides of the channel region via the low-concentration impurity region by introducing a larger dosage of the same type of impurity as that introduced in the low-concentration impurity region formation step;
a source region and a drain region being formed from the low-concentration impurity region and the high-concentration impurity region formed on each side of the channel region.

It is also possible to further include a step of measuring the sheet resistance of the semiconductor thin film between the polycrystallization step and the second impurity introduction step to determine the dosage of the impurity to be introduced in the second impurity introduction step based on the obtained sheet resistance.

It is preferable that the impurity introduced in the first impurity introduction step be p type and the impurities introduced in the second and the third impurity introduction steps be n type.

In the first impurity introduction step, the boron contained in the insulating substrate may be introduced into the semiconductor thin film by forming the semiconductor thin film directly on an insulating substrate formed of glass.

The object of the present invention can be achieved by using a method for fabricating a semiconductor device provided with a thin-film transistor comprising a semiconductor thin film comprising:
a first impurity introduction step of forming a gate electrode on an insulating substrate, forming a semiconductor thin film via an insulating film, and introducing either a first conductive impurity or a second conductive impurity into the semiconductor thin film, second conductive impurity comprising a conductive type that is opposite to the first conductive impurity;
a polycrystallization step of polycrystallizing the semiconductor thin film by subjecting it to intensive light or laser light;
a second impurity introduction step of forming a channel region having a layered structure of a first layer in which the first conductive impurity and the second conductive impurity are canceled and a second layer in which either the first conductive impurity or the second conductive impurity is dominant by introducing an impurity whose conductive type is opposite to the impurity that was introduced in the first impurity introduction step into the polycrystalline semiconductor thin film so that the first layer faces the gate electrode; and
a third impurity introduction step of forming a source region and a drain region in which the conductive type of the introduced impurity becomes dominant by introducing an impurity whose conductive type is opposite to the impurity of the second layer by covering a portion of the semiconductor thin film with a mask.

### BRIEF DESCRIPTION OF THE DRAWINGS

FIG. 1 is a cross-sectional view showing a fabrication process of a thin-film transistor in a semiconductor device according to the first embodiment of the present invention.

FIG. 2 is a cross-sectional view showing a fabrication process of a thin-film transistor in a semiconductor device according to the first embodiment of the present invention.

FIG. 3 is a schematic diagram of a sheet resistance meter in the fabrication process of the thin-film transistor.

FIG. 4 shows the result measuring the concentrations of B (boron) and P (phosphorus) in the channel region of the thin-film transistor.

FIG. 5 shows the relationship between gate voltage V_{GS} and drain current I_{D} in the thin-film transistor.

FIG. 6 is a cross-sectional view showing a fabrication process of a thin-film transistor in a semiconductor device of the second embodiment of the present invention.

FIG. 7 shows the result measuring a threshold voltage Vₜₕ relative to the doped amount of phosphorus when phosphorus is doped in the second impurity introduction step.

FIG. 8 shows the result measuring a threshold voltage Vₜₕ relative to the doped amount of phosphorus when phosphorus is doped in the second impurity introduction step.

FIG. 9 is a cross-sectional view of a liquid crystal display, which is a semiconductor device according to the third embodiment of the present invention.

FIG. 10 is a circuit diagram of an EL display, which is a semiconductor device according to the fourth embodiment of the present invention.

FIG. 11 shows a cross-sectional view of the principal part of the EL display.

FIG. 12 is a cross-sectional view of a thin-film transistor in a conventional semiconductor device.

FIG. 13 shows the relationship between a gate voltage V_{GS} and drain current I_{D} of a conventional thin-film transistor.

### BEST MODE FOR CARRYING OUT THE INVENTION

Embodiments of the present invention are explained below with reference to the drawings.

### First Embodiment

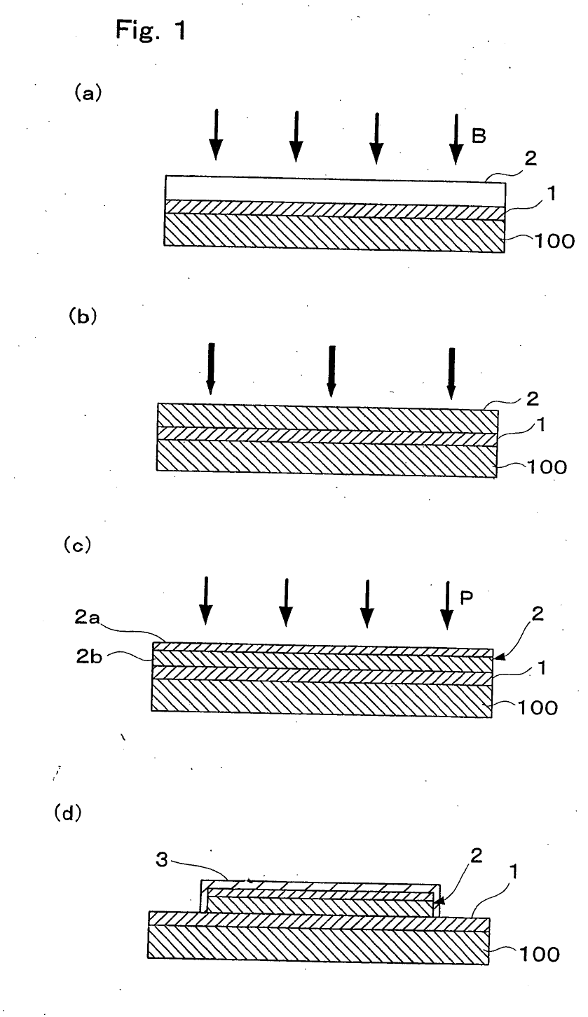

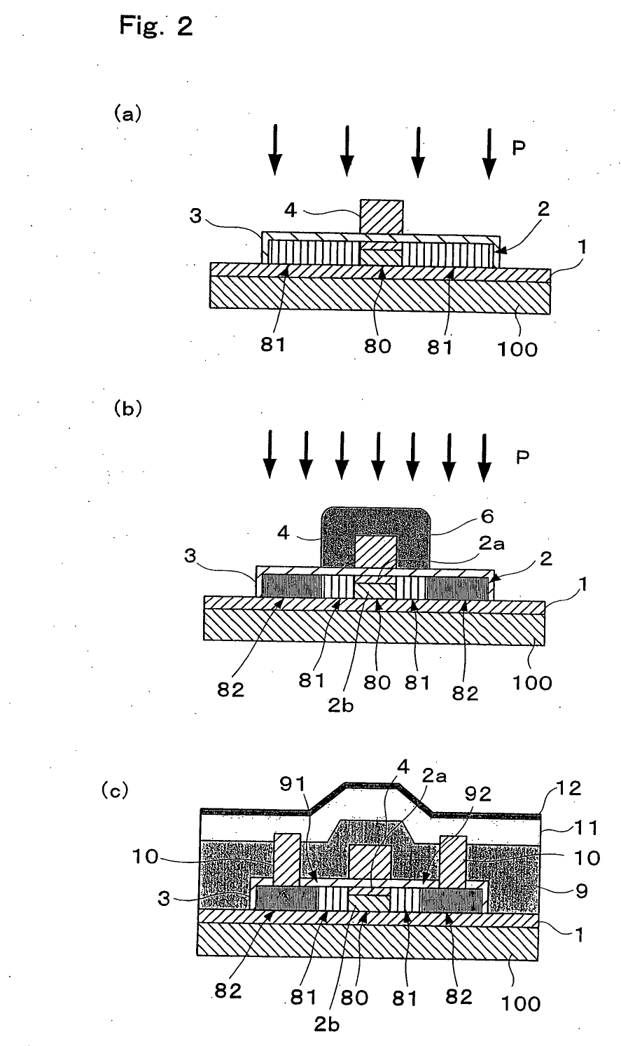

FIG. 1 and FIG. 2 are cross-sectional views showing steps for fabricating a thin-film transistor (TFT) in a semiconductor device according to the first embodiment of the present invention. The semiconductor device may include not only the TFT itself but also semiconductor circuits into which the TFT is integrated, electronic equipment, etc.

As shown in FIG. 1(a), a buffer layer 1, which serves as a primary layer, is first formed on an insulating substrate 100 that is composed of glass, etc. The buffer layer 1 can be formed by, for example, obtaining an SiO₂ film or an SiNx film by sputtering, etc., and the thickness of the buffer layer 1 may be approximately 100 nm to 1000 nm. In the present embodiment, the size of the insulating substrate 100 is set at 32 cm×40 cm.

A semiconductor thin film 2 composed of amorphous silicon is then formed to a thickness of 30 nm to 100 nm by plasma CVD, LPCVD, etc. It is also possible to form the semiconductor thin film 2 directly on the insulating substrate 100 without providing the buffer layer 1.

The semiconductor thin film 2 is heated in an oven or subjected to laser radiation to activate impurities contained in the semiconductor thin film 2, and the sheet resistance is then measured. This makes it possible to identify the extent of contamination caused by impurities, such as boron, in the air. The heating conditions may be, for example, 600° C. for about one hour. It is preferable to use a sheet resistance meter having a high-resistant measuring range. In the present embodiment, the “Mitsubishi Hiresta” is used.

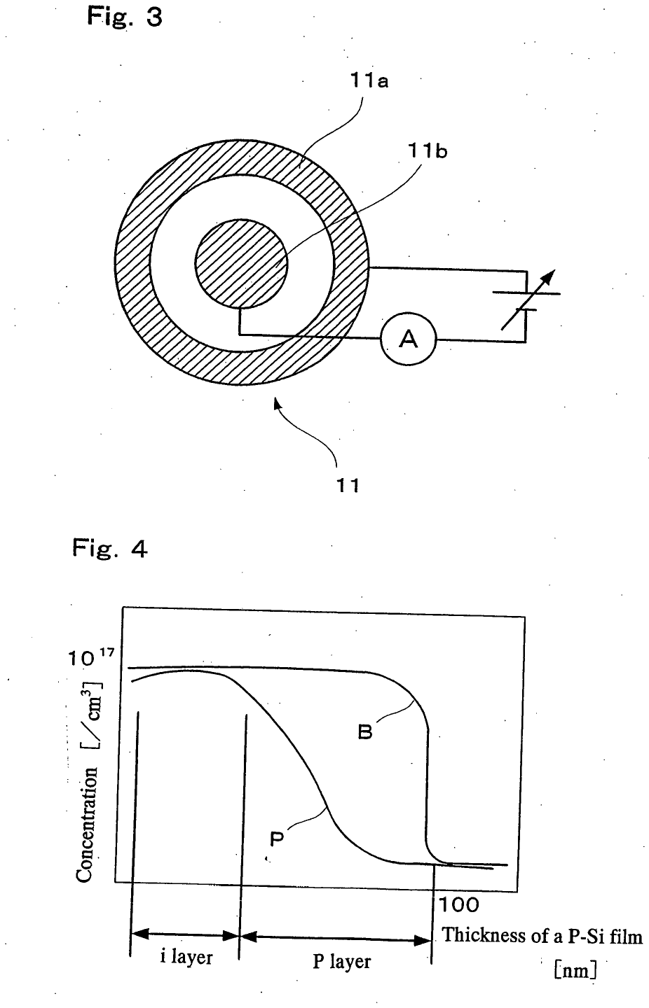

As shown in FIG. 3, this sheet resistance meter comprises an inner electrode 11b having a circular shape, as seen in a plan view, with a diameter of 3 mm and an outer electrode 11a having a ring-shape, as seen in a plan view, with an inside diameter of 6 mm, the inner electrode 11b being inserted into the outer electrode 11a. The sheet resistance meter measures sheet resistance based on the current when a predetermined voltage, i.e., approximately 1-1000 V, is applied with the outer electrode 11a and inner electrode 11b contacting the surface of the semiconductor thin film 2. Instead of using the above-described sheet resistance meter, it is also possible to measure the sheet resistance by forming a metal pattern having a shape similar to the above-mentioned outer electrode 11a and inner electrode 11b on the surface of the semiconductor thin film 2, and other measuring equipment may be used as long as a high sheet resistance can be measured.

After the measurement, if the sheet resistance is higher than a predetermined value (for example, 1×10⁹ Ω/□), the first impurity introduction step is performed using ion-implantation device. In this step, a p-type impurity is introduced into the semiconductor thin film 2. In the present embodiment, B (boron) is used as the element to be introduced, the accelerating voltage is set at 10 kV, the dosage is set at 1×10¹¹/cm², the impurity ions generated from the ion source are subjected to mass separation to extract only the desired ions, the ions are introduced to the semiconductor thin film 2 by scanning the film with an ion beam obtained by forming the ions into a beam-like shape so that the concentration of the introduced impurity is 1×10¹⁷/cm³.

In the present embodiment, an ion-implantation device manufactured by Nisshin Ion Equipment, Co., Ltd. is used. This ion-implantation device is provided with a magnetic field deflector. Using magnetic field deflection, the ion-implantation device can implant ions by scanning with an ion beam having such a large current that it would cause difficulties in scanning by electrostatic deflection. The size of the substrate used may be larger than 32 cm×40 cm, and it is possible to efficiently process a large insulating substrate 100 having an area of 1000 cm² or more. In the ion-implantation device, the maximum beam current is 16 mA, applied energy is variable in the range of 10 KeV to 100 KeV, and the dosage is controllable in the range of 1×10¹¹/cm² to 1×10²⁰/cm². The implantable ions are P (phosphorus) and B (boron).

When hydrogen contained in the semiconductor thin film 2 needs to be eliminated, as in the case where the plasma CVD method is employed to form the semiconductor thin film 2, annealing is conducted by placing the insulating substrate 100 in a nitrogen atmosphere and heating it at 400-450° C. for about one hour. This dehydrogenation-annealing step may be conducted by lamp annealing, using RTA, etc., and it is also possible to conduct such a step before the first impurity introduction step.

In contrast, when the measured sheet resistance of the semiconductor thin film 2 is less than a predetermined value (for example, 1×10⁹ Ω/□), it indicates that the first impurity introduction step has already been completed by the sufficient introduction of boron and like impurities in the air into the semiconductor thin film 2, and therefore the introduction of an impurity using an ion-implantation device and the like becomes unnecessary. In particular, when the semiconductor thin film 2 is formed directly onto an insulating substrate 100 composed of glass without forming a buffer layer 1, boron and like impurities contained in the insulating substrate 100 are readily introduced to the semiconductor thin film 2 and the first impurity introduction step tends to become unnecessary, reducing the required number of fabrication steps. It is also possible to make the semiconductor thin film 2 become p-like character by using a laser energy condition of 250 mJ/m² to 500 mJ/m².

Subsequently, as shown in FIG. 1(b), amorphous silicon in the semiconductor thin film 2 is converted into polycrystalline silicon by laser annealing, solid-phase growth, etc.

Thereafter, using the above-described sheet resistance meter, the sheet resistance of the polycrystalline-silicon semiconductor thin film 2 is measured. The lower the impurity concentration of the semiconductor thin film 2, the greater the sheet resistance. Because they have a correlation, it is possible to learn the impurity concentration of the semiconductor thin film 2 based on the sheet resistance.

As shown in FIG. 1(c), the second impurity introduction step is then conducted based on the measured sheet resistance. This step is conducted to introduce n-type impurities to the surface of the semiconductor thin film 2, and to control the threshold voltage Vₜₕ of the TFT by adjusting the impurity concentration in the area that is formed into a channel region in a later step. As described above, the sheet resistance has a correlation with the amount of p-type impurity already doped, and therefore the amount of the n-type impurity is selected based on the sheet resistance and doping is conducted using the ion-implantation device.

In the second impurity introduction step, the implantation depth is selected so that the impurity is mostly introduced into an ultra-shallow portion near the surface of the semiconductor thin film in the thickness direction. In the present embodiment, the specific conditions for this step are as follows: an accelerating voltage of 10 kV, an ion beam current of 0.01 μA-10 μA, a scanning frequency in the horizontal direction of 1 Hz, a scanning speed in the vertical direction of 30 mm/sec, an overlap in the beam spot of 66.7%, a scanning cycle in the vertical direction of 8 to 10 cycles, and a total time of 300 sec to 400 sec. This step may be conducted before the above-described dehydrogenation-annealing step, or after the gate insulating film 3 formation step described later. The impurity introduction may be conducted using a semiconductor implanter, etc., and it is also possible to introduce the impurity by scanning a glass substrate with a ribbon beam using a mass separation type implanter.

Because a p-type impurity was already introduced into the semiconductor thin film 2, impurities having opposite conductive types in the region where an n-type impurity was introduced are canceled by each other and an intrinsic-like i-layer 2a is formed as shown in FIG. 1(c). Below the i-layer 2a, a p-type layer 2b in which the p-type impurity becomes dominant is formed in the thickness direction. In other words, the first and second impurity introduction steps give the semiconductor thin film 2 a layered structure wherein the i-layer 2a as the first layer and the p-type layer 2b as the second layer are laminated.

Thereafter, as shown in FIG. 1(d), the semiconductor thin film 2 is patterned into an island-shape by etching to form a thin-film transistor device region. A gate insulating film 3 is formed so as to cover the etched semiconductor thin film 2. The gate insulating film 3 can be formed by depositing an SiO₂ film by employing, for example, plasma CVD, atmospheric pressure CVD, decompression CVD, ECR-CVD, sputtering and the like with a thickness of 50 nm to 600 nm.

On the insulating substrate 100, Al, Ti, Mo, W, Ta or their alloy is formed into a film with a thickness of 200 nm to 800 nm and patterned into a predetermined shape, and a gate electrode 4 is then formed on the gate insulating film 3.

A third impurity introduction step wherein an n-type impurity is implanted is conducted using the ion-implantation device and utilizing the gate electrode 4 as a mask. In other words, a low-concentration impurity region (LDD region) 81 of the TFT as shown in FIG. 2(a) is formed by mass separating impurity ions generated from the ion source in order to extract only phosphorus, which is the desired ion, and introducing the ion to the semiconductor thin film 2, using the gate electrode 4 as a mask, by scanning the film with an ion beam obtained by forming ions into a beam-like shape in such a manner that the concentration of the introduced impurity is less than 1×10¹⁴/cm². It is necessary to set the dosage so that the concentration of phosphorus in the LDD region 81 becomes greater than that of the boron, preferably, in the range of 6×10¹²/cm² to 5×10¹³/cm². This makes the n-type impurity in the LDD region 81 dominant and the portion below the gate electrode 4 becomes the channel region 80.

After forming a resist pattern 6 around the gate electrode 4 as shown in FIG. 2(b), an ion shower is conducted using ion doping equipment. In other words, a high-concentration impurity region 82 of the TFT is formed by first generating impurity ions from another ion source without mass separating them, then subjecting these impurity ions containing phosphorus, which is the desired ion, to electric acceleration to form an ion shower, and introducing the resulting ion shower to the semiconductor thin film 2 to produce a dosage of 1×10²¹/cm³ or more without scanning. In the present embodiment, the dosage is approximately 1×10²¹/cm². The ion doping equipment provides a high throughput by taking impurity ions out of a bucket-type chamber in a single step and irradiating the entire surface of the insulating substrate 100, thus making the time necessary for processing one substrate approximately one minute including conveyance. The ion shower may also be conducted using the previously described ion-implantation device instead of the ion doping equipment.

In the third impurity introduction step, a source region 91 and a drain region 92 are formed in a low-concentration impurity region 81 and a high-concentration impurity region 82, which are each formed on both sides of the channel region 80. Because a p-type impurity is dominant in the p-type layer 2b formed in the channel region 80, and an n-type impurity is dominant in the source region 91 and drain region 92, an npn junction is formed between the source region 91 and the drain region 92 along the surface of the semiconductor thin film. When integrating a CMOS circuit by forming it on the insulating substrate 100, a resist pattern for a p-channel transistor is formed in addition to a resist pattern 6 for an n-channel transistor, then the gas system for the ion source is changed to 5% B2H6/H2, and B ions are implantated at a dosage of approximately 1×10²¹/cm².

As shown in FIG. 2(c), an interlayer insulating film 9 composed of PSG or the like is then formed on the insulating substrate 100 so as to produce a film thickness of approximately 600 nm. Next, the dopant introduced into the semiconductor thin film 2 is activated by thermal treatment at 300° C.-400° C. Laser activating annealing may also be conducted instead of this low-temperature activating annealing.

Thereafter, contact holes are formed in the interlayer insulating film 9, metal films composed of Al—SI or the like are formed by sputtering and patterning into a predetermined shape, and then the metal films are formed into wiring electrodes 10. An SiO₂ film 11 and an SiNx film 12 cover the top of the wiring electrodes 10 in this order. The total thickness of these films is approximately 200 nm to 400 nm. The insulating substrate 100 is then placed in a nitrogen atmosphere and subjected to hydrogenation by annealing at approximately 350° C. for about one hour, completing the TFT. The highest temperature for processing the TFT is approximately 400° C. to 600° C. in the step of dehydrogenation by annealing.

In a polycrystalline-silicon TFT comprising the channel region 80 wherein the i-layer 2a and the p-type layer 2b are laminated, it is possible to form an npn junction between the source region 91 and the drain region 92, thereby reducing the leak current when the gate voltage is negative, by making the conductive type of the source region 91 and the drain region 92 opposite to the conductive type that is dominant in the p-type layer 2b.

By positioning the gate electrode 4 so it faces the i-layer 2a, the application of small positive gate voltage will form an n-type region in the i-layer 2a due to the induction of electrons, causing current to flow across the source region 91 and the drain region 92. This makes it easier to control the threshold voltage Vₜₕ and makes it possible to bring the threshold voltage Vₜₕ close to 0 V.

The definition of the i-layer 2a is described later. From the viewpoint of reducing leak current, the ratio of the thickness of the i-layer 2a relative to the total thickness of the channel region 80 is preferably not more than 50%, more preferably not more than 30% and most preferably not more than 10% to obtain a more perfect npn junction between the source region 91 and the drain region 92 in the OFF-state. In contrast, from the viewpoint of controlling the threshold voltage Vₜₕ, in order to obtain a channel in the ON-state, the thickness of the i-layer 2a is preferably not less than 1 nm, more preferably not less than 2 nm and most preferably not less than 3 nm. In other words, a thinner i-layer 2a is better for reducing the leak current, and a thicker i-layer 2a is better for improving the control of the threshold voltage Vₜₕ. Therefore, it is preferable to select a thickness for the i-layer 2a that suits both of these characteristics. In the present embodiment, the thickness of the semiconductor thin film 2 is 100 nm and the thickness of the i-layer 2a is 30 nm.

FIG. 4 is a graph showing the concentrations of B (boron) and P (phosphorus) in the channel region 80 as measured by the present inventors. In this graph, the left end shows their concentrations on the surface of the channel region 80. Near the surface of the channel region 80, which is shown at the left end of the graph, the concentrations of boron and phosphorus are substantially the same. In the present embodiment, the region having the concentration variance of less than 5×10¹⁶/cm³ in the thickness direction is defined as an i-layer. The concentration variance in the i-layer between the p-type impurity and the n-type impurity correlates with the sheet resistance on the surface of the i-layer. The smaller the variance of the concentrations, the greater the sheet resistance. Therefore, the sheet resistance on the surface of the i-layer is greater than 1×10⁹ Ω/□.

Below the i-layer, the concentration of boron is substantially stable; however, the concentration of phosphorus gradually decreases, and therefore a p-type layer in which boron is dominant is formed. The p-type layer corresponds to the region other than the i-layer in the channel region 80.

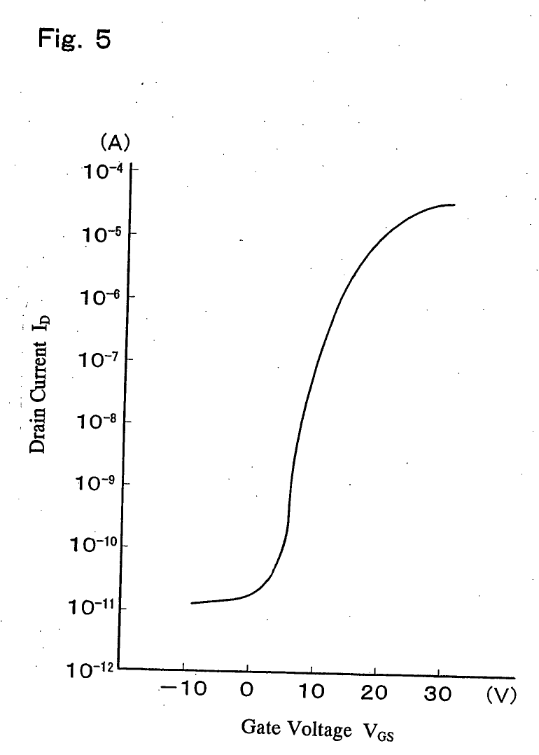

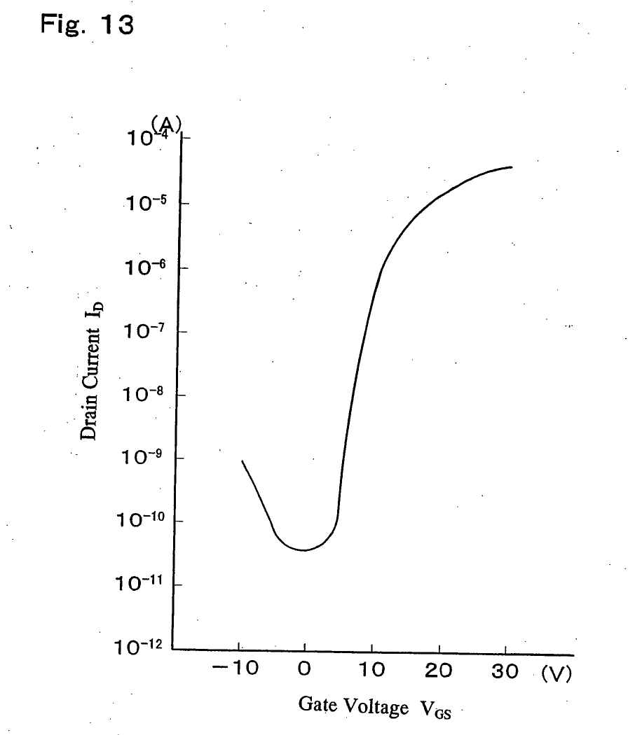

FIG. 5 is a graph showing the relationship between the gate voltage V_{GS} and the drain current I_{D} when the drain voltage V_{DS} is 4 V. When the result is compared with that of a conventional TFT, as shown in FIG. 13, the variance in characteristics is very slight in the region where the gate voltage V_{GS} is positive; however, in the region where the gate voltage V_{GS} is negative, the TFT of the present embodiment shows less rise in the drain current I_{D} and a reduction in the OFF current itself.

### The Second Embodiment

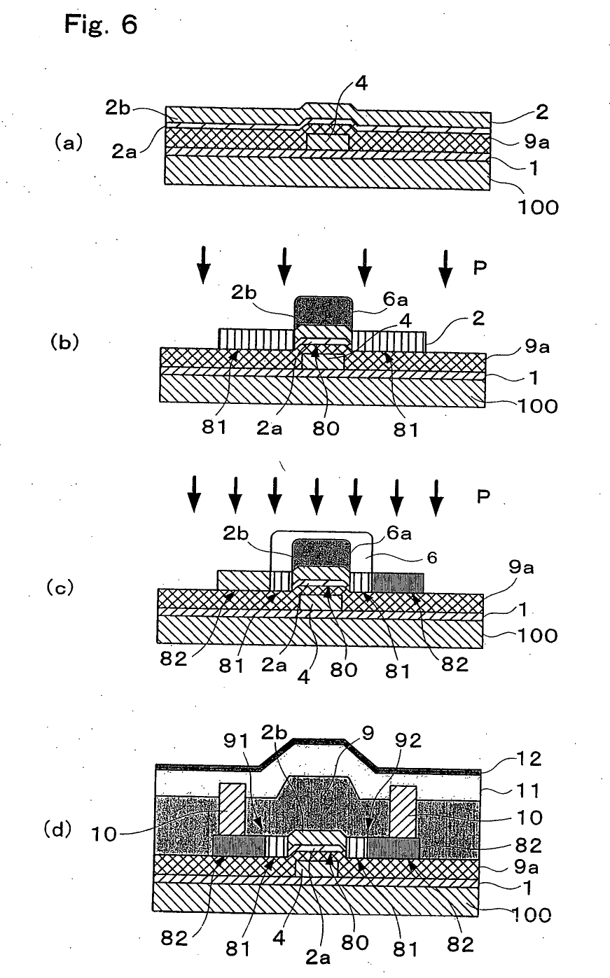

The polycrystalline-silicon TFT in the first embodiment is generally called a coplanar structure or stagger structure. It is also possible to apply the present invention to a polycrystalline-silicon TFT having a bottom-gate structure or inverted-stagger structure. The steps for fabricating such a TFT are shown in FIG. 6. In this figure, the constituent components that are the same as those in the first embodiment share the same numbers as these in the first embodiment.

As shown in FIG. 6(a), an SiO₂ film or an SiNx film having a thickness of approximately 100 nm to 200 nm is first formed on an insulating substrate 100 composed of glass or the like, to obtain a buffer layer 1. The dimensions of the insulating substrate 100 are 30 cm×35 cm. A metal film composed of Al, Ta, Mo, W, Cr or their alloy is formed to a thickness of 100 nm to 200 nm, patterned into a predetermined shape, and formed into gate electrode 4.

SiNx is then deposited to a film thickness of 50 nm by plasma CVD, atmospheric pressure CVD, decompression CVD or the like, to obtain a gate insulating film 9a. Subsequently, a semiconductor thin film 2 composed of amorphous silicon is continuously formed thereon to a film thickness of approximately 30 nm to 100 nm. If plasma CVD is employed here, annealing is conducted in a nitrogen atmosphere at 400° C. to 450° C. for about one hour to remove hydrogen from the film. The dehydrogenation by annealing may also be conducted by employing lamp annealing using RTP, etc.

After heating in the same manner as in the first embodiment, the sheet resistance in the semiconductor thin film 2 is measured. A sheet resistance meter similar to that used in the first embodiment can be used. If the sheet resistance measured is beyond a predetermined value (for example, 1×10⁹ Ω/□), as in the first embodiment, a first impurity introduction step is conducted using an ion-implantation device. The doping conditions are the same as those in the first embodiment. If the sheet resistance of the semiconductor thin film 2 is less than a predetermined value (for example, 1×10⁹ Ω/□), it indicates that impurities such as boron or the like contained in the air have been satisfactorily introduced into the semiconductor thin film 2, thereby completing the first impurity introduction step.

Subsequently, amorphous silicon in the semiconductor thin film 2 is converted into polycrystalline silicon by laser annealing, solid-phase growth, etc. The sheet resistance of the semiconductor thin film 2 composed of polycrystalline silicon is measured using a sheet resistance meter.

Thereafter, based on the measured sheet resistance, as in the first embodiment, the second impurity introduction step is conducted. Because the sheet resistance correlates with the amount of the p-type impurity already doped, the amount of the n-type impurity, which is introduced to control the threshold voltage Vₜₕ, is selected based on the sheet resistance and the n-type impurity is introduced using an ion-implantation device. In the second impurity introduction step, the introduction depth is selected so that the impurity is mostly introduced to the deepest portion, which is in the vicinity of the gate electrode 4 in the thickness direction. In the present embodiment, the specific conditions are as follows: an accelerating voltage of 100 kV, an ion beam current of 15 μA, a scanning frequency in the horizontal direction of 1 Hz, a scanning speed in the vertical direction of 30 mm/sec, an overlap in the beam spot of 66.7%, a scanning cycle in the vertical direction of 8 to 10 cycles, and a total time of 300 sec to 400 sec.

Because the p-type impurity was already introduced into the semiconductor thin film 2, the p-type impurity and n-type impurity are canceled by each other in the vicinity of the gate electrode 4 to which n-type impurity was introduced, and an intrinsic-like i-layer 2a is formed. Above the i-layer 2a, a p-type layer 2b in which the p-type impurity is dominant in the thickness direction is formed. In other words, the first and second impurity introduction steps give the semiconductor thin film 2 a layered structure wherein the i-layer 2a as the first layer and the p-type layer 2b as the second layer are laminated.

Thereafter, as shown in FIG. 6(b), the semiconductor thin film 2 is etched into an island-shape to form a thin-film transistor device region. An SiO₂ film having a thickness of 100 nm to 300 nm is formed so as to cover the etched semiconductor thin film 2 and patterned into a predetermined shape using the gate electrode 4 as a mask, obtaining a resist pattern 6a.

The third impurity introduction step, wherein an n-type impurity is implanted, is conducted using an ion-implantation device. In other words, a low-concentration impurity region (LDD region) 81 of the TFT is formed by first mass separating impurity ions generated from an ion source to extract only phosphorus, which is the desired ion, then introducing the ions into the semiconductor thin film 2 by scanning the semiconductor thin film 2 with an ion beam obtained by forming the ions into a beam-like shape in such a manner that the concentration of the introduced impurity is less than 1×10¹⁴/cm², and using the resist pattern 4 as a mask. It is necessary to set the dosage so that the concentration of phosphorus in the LDD region 81 is greater than that of boron, specifically, in the range of 6×10¹²/cm² to 5×10¹³/cm². This makes the n-type impurity in the LDD region 81 dominant and forms the channel region 80 below the resist pattern 6.

After further forming a resist pattern 6 so as to cover the resist pattern 6a as shown in FIG. 6(c), an ion shower is conducted. In other words, a high-concentration impurity region 82 of the TFT is formed by generating impurity ions from another ion source without mass separating them, then subjecting these impurity ions containing phosphorus, which is the desired ion, to electric acceleration to form an ion shower, and introducing the resulting ion shower to the semiconductor thin film 2 to produce a dosage of 1×10²¹/cm³ or more without scanning. In the present embodiment, the dosage is approximately 1×10²¹/cm². In the present embodiment, the dosage is approximately 1×10²¹/cm². The fourth impurity implantation step may be conducted using the ion-implantation device instead of the ion doping equipment.

A source region 91 and a drain region 92 are thereby formed in a low-concentration impurity region 81 and a high-concentration impurity region 82, which are each formed on both sides of the channel region 80 in the third impurity introduction step.

The dopant introduced into the semiconductor thin film 2 is then activated by annealing at approximately 300° C. to 400° C. As in the first embodiment, activation annealing may also be conducted by laser annealing.

Because a p-type impurity is dominant in the p-type layer 2b formed in the channel region 80, and an n-type impurity is dominant in the source region 91 and drain region 92, an npn junction is formed between the source region 91 and the drain region 92 along the surface of the semiconductor thin film. When integrating a CMOS circuit by forming it on the insulating substrate 100, a resist pattern for a p-channel transistor is formed in addition to a resist pattern 6 for an n-channel transistor, then the gas system for the ion source is changed to 5% B2H6/H2, and B⁺ ions are implanted at a dosage of approximately 1×10²¹/cm².

As shown in FIG. 6(d), an interlayer insulating film 9 composed of PSG or the like is then formed on the insulating substrate 100 so as to produce a film thickness of approximately 600 nm. Next, the dopant introduced into the semiconductor thin film 2 is activated by thermal treatment at 300° C. to 400° C. Laser activating annealing may also be conducted instead of this low-temperature activating annealing.

Thereafter, contact holes are formed in the interlayer insulating film 9, metal films composed of Al—Si or the like are formed by sputtering and patterning into a predetermined shape, and then formed into wiring electrodes 10. An SiO₂ film 11 and an SiNx film 12 cover the wiring electrodes 10 in this order. The total thickness of these films is approximately 200 nm to 400 nm. The insulating substrate 100 is then placed in a nitrogen atmosphere and subjected to hydrogenation by annealing at approximately 350° C. and for about one hour, completing the TFT. This annealing process introduces the hydrogen contained in the SiO₂ film 11 into the semiconductor thin film 2, improving the operating characteristics of the TFT.

In such a TFT, as described in the first embodiment, it is possible to form an npn junction between the source region 91 and the drain region 92, thereby reducing the leak current when the gate voltage is negative, by making the conductive type of the source region 91 and the drain region 92 opposite to the conductive type that is dominant in the p-type layer 2b.

By positioning the gate electrode 4 so it faces the i-layer 2a, the application of a small positive gate voltage will form an n-type region in the i-layer 2a due to the induction of electrons, causing current to flow across the source region 91 and the drain region 92. This makes it easier to control the threshold voltage Vₜₕ and makes it possible to bring the threshold voltage Vₜₕ close to 0 V.

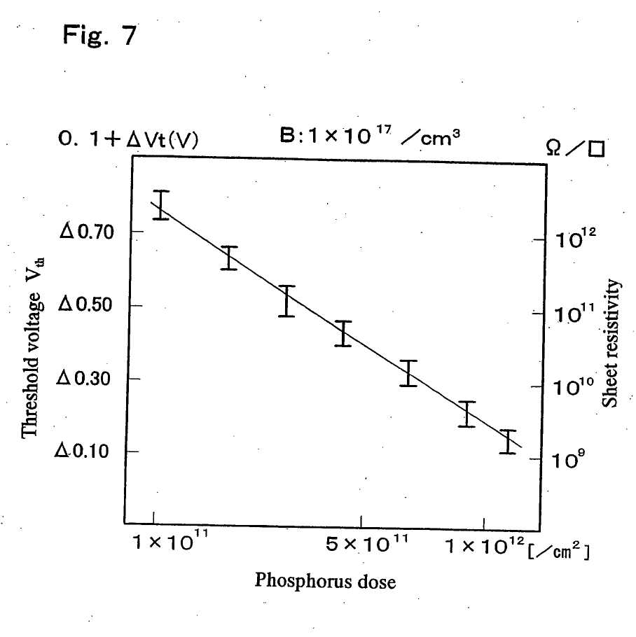

FIG. 7 is a graph showing the relationship of the threshold voltage Vₜₕ measured relative to the total amount of phosphorus introduced after setting the boron concentration of the semiconductor thin film 2 to 1×10¹⁷/cm³ in the first impurity introduction step, and intorducing phosphorus in the second impurity introduction step. As shown in the figure, the dosage of the phosphorus and the threshold voltage Vₜₕ have a certain relationship, and when the dosage of phosphorus is 9×10¹¹/cm², the threshold voltage Vₜₕ is approximately 0.2 V, therefore making it possible to control the threshold voltage Vₜₕ to be satisfactorily low. Because the variation of the threshold voltage Vₜₕ relative to an arbitrary phosphorus dosage is approximately 0.1 V, it is possible to reduce the variation and accurately control the threshold voltage Vₜₕ. As is clear from the figure, the threshold voltage Vₜₕ correlates with the sheet resistance, so it is possible to learn the threshold voltage Vₜₕ by measuring the resistance after the second impurity introduction step.

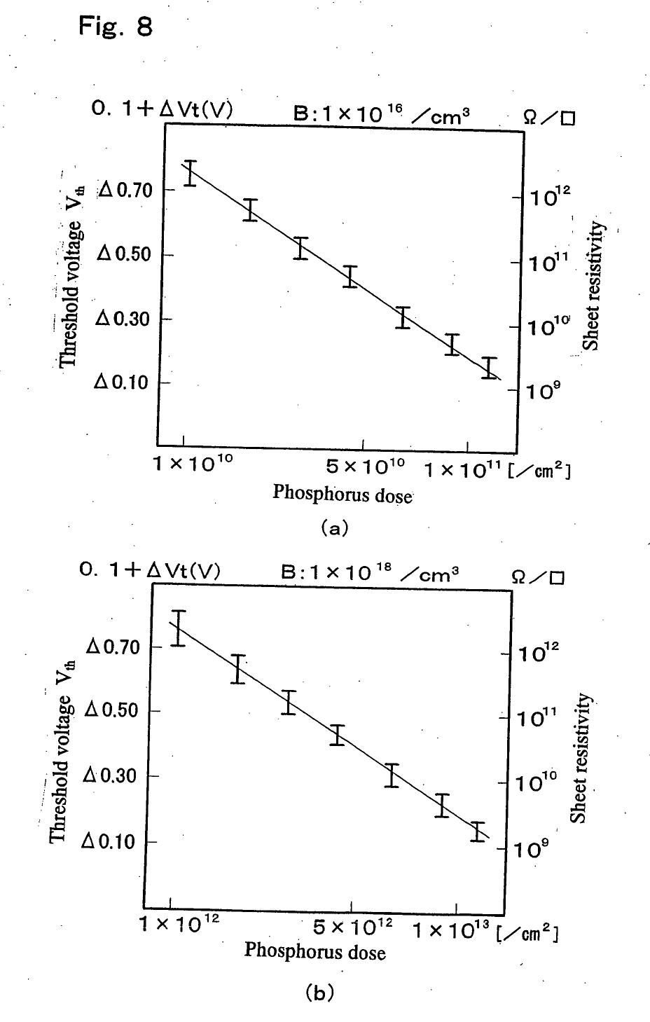

FIG. 7 shows the measurement results when the concentration of boron introduced during the first impurity introduction step is 1×10¹⁷/cm³; however, the present inventors confirmed that the phosphorus dosage, threshold voltage Vₜₕ and sheet resistance have a correlation even at a different concentration. FIGS. 8(a) and 8(b) show the measurement results when the boron concentration is 1×10¹⁶/cm³ and 1×10¹⁸/cm³, respectively.

### The Third Embodiment

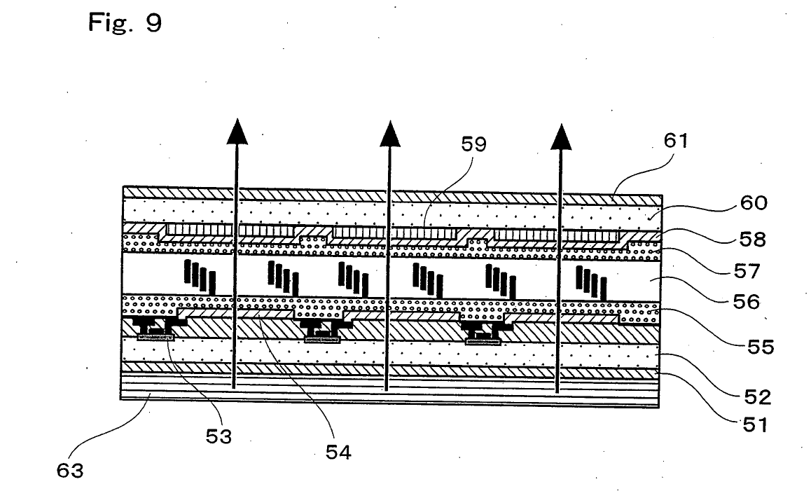

A liquid crystal display device is shown in FIG. 9 as an example of a semiconductor device employing a polycrystalline-silicon TFT. As shown in this figure, this liquid crystal display device comprises a TFT array substrate 52 and an opposing substrate 60 positioned so as to face each other.

The TFT array substrate 52 comprises TFTs 53, which are switching elements, arranged in a matrix on the upper side (opposing substrate 60 side). The TFTs 53 can be formed in the same manner as that used to form the TFT in the first or second embodiment.

The opposing substrate 60 is a glass insulating substrate provided with a color filter 59 and a transparent electrode 58 on the bottom side (TFT array substrate 52 side). Between the TFT array substrate 52 and the opposing substrate 60, a liquid crystal layer 56 is sandwiched between orientation films 55 and 57, which are composed of polyimide or the like. Furthermore, polarizing plates 51 and 60 are respectively attached to the surfaces of the TFT array substrate 52 and the opposing substrate 60 that are opposite to the surfaces facing each other. Below the TFT array substrate 52, a backlight 63 is provided to improve visibility.

Use of a liquid crystal display device having such a structure provides uniform and stable display images without luminescent spot defects by reducing leak current in the TFT 53 and improving control of the threshold voltage Vₜₕ, and also makes it possible to save energy consumption by controlling the drive voltage of the TFT 53.

### The Fourth Embodiment

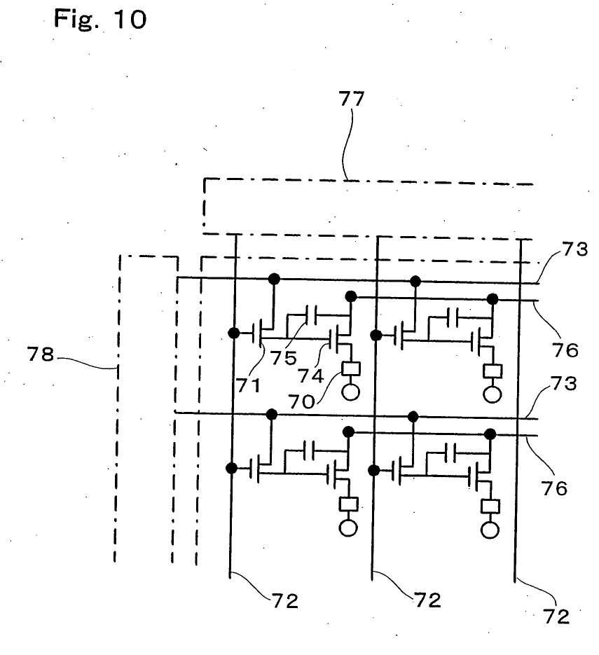

FIG. 10 shows a circuit diagram of an EL display device as an example of a semiconductor device using the above-described polycrystalline-silicon TFT. The EL display device is provided with a TFT array substrate. The TFT array substrate comprises a switching TFT 71, a drive TFT 74 and an EL element 70 in each pixel region. A gate electrode in the switching TFT 71 is connected to a gate signal wire 72, and a drain electrode is connected to a drain signal wire 73. A source electrode is connected to a gate electrode in a drive TFT 74. A source electrode of the drive TFT 74 is connected to a positive electrode of the EL element 70, and the drain electrode is connected to a power supply wire 76. Symbol 75 stands for a signal-retaining capacitor.

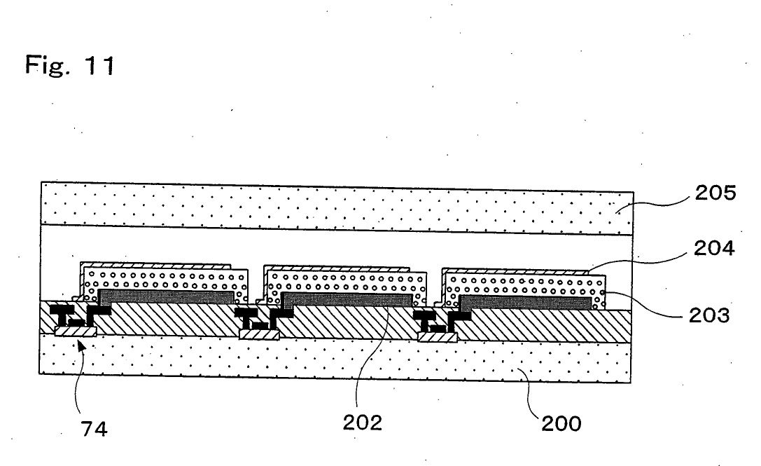

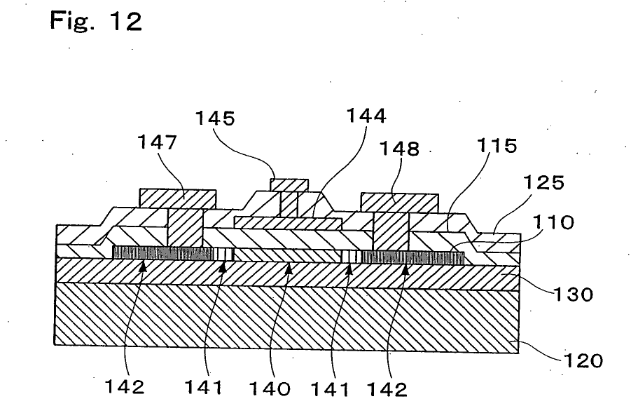

As shown in FIG. 11, the drive TFT 74 is disposed on a TFT array substrate 200. The EL element 70 is fabricated by forming layers of a positive electrode 202, an organic layer 203, and a negative electrode 204. The top of the EL element 70 is covered with a glass plate 205.

As shown in FIG. 10, when a pulse signal sent to the gate signal wire 72 from a drive circuit 77 is applied to the gate electrode of the switching TFT 71, the switching TFT 71 turns on, and a drain signal sent from the drive circuit 78 to the drain signal wire 73 is applied to the gate electrode of the drive TFT 74. This turns the drive TFT 74 on, and current from the power supply wire 76 is supplied to the EL element 70, making the EL element 70 emit light.

By reducing the leak current in the switching TFT 71 and the drive TFT 74, this EL display device eliminates the possibility of the drive TFT 74 turning on when the switching TFT 71 is in the OFF-state, thus preventing the EL element 70 from abnormally emitting light. Furthermore, by improving the control of the threshold voltage Vₜₕ, it is possible to suppress variations in the current supplied to the EL element 70. As a result, uneven brightness in the displayed image can be reduced and an excellent image display can be achieved.

For example, when an eight-level gray scale is displayed, the design generally calls for noise to be 1/10 (20 dB) relative to the signal. It is assumed that the primary cause of noise is variation in the TFT characteristics, and therefore use of the present invention makes it easier to meet the noise requirement. Because it is possible to increase the ON-current while reducing the leak current, the brightness of the EL element 70 can be easily maintained, increasing its life.

### Other Embodiments

Several embodiments of the present invention are described in detail above; however, the actual embodiments of the present invention are not limited to those described above. For example, an i-layer and a p-type layer in a channel region may be formed in other fabricating processes.

In the embodiments described above, boron or a like p-type impurity is introduced in the first impurity introduction step, and phosphorus or a like n-type impurity is introduced in the second impurity introduction step to form the i-layer and p-type layer in the channel region; however, it is also possible to form the i-layer and p-type layer in the channel region by introducing phosphorus or a like n-type impurity in the first impurity introduction step and introducing boron or a like p-type impurity in the second impurity introduction step. In other words, it is possible to form a layered structure having an intrinsic-like i-layer and an n-type layer in which n-type impurity is dominant in the thickness direction. In this case, by implanting a p-type impurity in the third impurity introduction step, a pnp junction is formed along the surface of the semiconductor thin film between the source region 91 and the drain region 92, obtaining the same effects as in the above embodiments.

In the above embodiments, B (boron) is used as a p-type impurity and P (phosphorus) is used as an n-type impurity; however, it is also possible to use Al (aluminum), Ga (gallium), In (indium), Tl (thallium), etc., as a p-type impurity and N (nitrogen), As (arsenic), Sb (antimony), Bi (bismuth) or the like as an n-type impurity. The impurity can be implanted by merely combining these impurities as described.

Examples of semiconductor devices can also include those other than liquid crystal display devices and EL display devices, and it is possible to employ the present invention to, for example, a switching element of an image sensor, etc.

1. A semiconductor device comprising:
a thin-film transistor comprising a polycrystalline semiconductor thin film formed on an insulating substrate;
a channel region in the semiconductor thin film; and
a source region and a drain region each disposed on a different end of the channel region;
the channel region comprising both a first conductive impurity and a second conductive impurity, the second conductive impurity being opposite to the first conductive impurity, and structured by layering a first layer in which the first conductive impurity and the second conductive impurity are canceled and a second layer in which either the first conductive impurity or the second conductive impurity is dominant;
a gate electrode being formed so as to face the first layer via an insulating film; and
the source region and the drain region being formed of the conductive impurity opposite to the one that is dominant in the second layer.

2. A semiconductor device according to claim 1, wherein the gate electrode is formed on the semiconductor thin film.

3. A semiconductor device according to claim 1, wherein the gate electrode is formed between the insulating substrate and the semiconductor thin film.

4. A semiconductor device according to claim 1, wherein the source region and the drain region comprise a high-concentration impurity region and a low-concentration impurity region, the low-concentration impurity region being disposed between the channel region and the high-concentration impurity region and having an impurity concentration that is lower than that of the high-concentration impurity region.

5. A semiconductor device according to claim 1, wherein the difference in concentration between the first conductive impurity and the second conductive impurity in the first layer is less than 5×10¹⁶/cm³.

6. A semiconductor device according to claim 1, wherein the thickness of the first layer is not less than 1 nm and not more than 50% of the total thickness of the channel region.

7. A semiconductor device according to claim 1, wherein the sheet resistance of the first layer is not less than 1×10⁹ Ω/□.

8. A semiconductor device according to claim 1, wherein the source region and the drain region are n type, and the second layer is a p type layer in which p type is dominant.

9. A semiconductor device according to claim 1, wherein the insulating substrate is formed of glass and the semiconductor thin film is formed directly on the insulating substrate.

10. A method for fabricating a semiconductor device provided with a thin-film transistor comprising a semiconductor thin film comprising:
a first impurity introduction step of forming, on an insulating substrate, a semiconductor thin film to which either a first conductive impurity or a second conductive impurity is introduced into an insulating substrate, the second conductive impurity being the opposite conductive type to that of the first conductive impurity;
a polycrystallization step of polycrystallizing the semiconductor thin film by subjecting it to intensive light or laser light;
a second impurity introduction step of forming a channel region having a layered structure of a first layer in which the first conductive impurity and the second conductive impurity are canceled and a second layer in which either the first conductive impurity or the second conductive impurity is dominant by introducing an impurity whose conductive type is opposite to that of the impurity introduced in the first impurity introduction step into the polycrystalline semiconductor thin film;
a gate electrode formation step of forming a gate electrode on the first layer via the insulating film; and
a third impurity introduction step of forming a source region and a drain region in which the conductive type of the introduced impurity becomes dominant by introducing an impurity of a conductive type that is opposite to that of the second layer by using the gate electrode as a mask.

11. A method for fabricating a semiconductor device according to claim 10, wherein the third impurity introduction step comprises:
a low-concentration impurity region formation step of forming a low-concentration impurity region in which the conductive type of the introduced impurity becomes dominant by introducing an impurity of a conductive type that is opposite to that of the second layer by using the gate electrode as a mask, and forming a channel region below the gate electrode; and
a high-concentration impurity region formation step of covering a part of the region adjacent to the channel region, and forming high-concentration impurity regions on both sides of the channel region via the low-concentration impurity region by introducing a larger dosage of the same type of impurity as that introduced in the low-concentration impurity region formation step;
a source region and a drain region being formed from the low-concentration impurity region and the high-concentration impurity region formed on each side of the channel region.

12. A method for fabricating a semiconductor device according to claim 10, which further comprises a step of measuring the sheet resistance of the semiconductor thin film between the polycrystallization step and the second impurity introduction step to determine the dosage of the impurity introduced in the second impurity introduction step based on the obtained sheet resistance.

13. A method for fabricating a semiconductor device according to claim 10, wherein the impurity introduced in the first impurity introduction step is p type and that introduced in the second and the third impurity introduction steps is n type.

14. A method for fabricating a semiconductor device according to claim 10, wherein, in the first impurity introduction step, the boron contained in the insulating substrate is introduced into the semiconductor thin film by forming the semiconductor thin film directly on the insulating substrate formed of glass.

15. A method for fabricating a semiconductor device provided with a thin-film transistor comprising a semiconductor thin film comprising:
a first impurity introduction step of forming a gate electrode on an insulating substrate, forming a semiconductor thin film via an insulating film, and introducing either a first conductive impurity or a second conductive impurity into the semiconductor thin film, second conductive impurity of a conductive type that is opposite to the first conductive impurity;
a polycrystallization step of polycrystallizing the semiconductor thin film by subjecting it to intensive light or laser light;
a second impurity introduction step of forming a channel region having a layered structure of a first layer in which the first conductive impurity and the second conductive impurity are canceled and a second layer in which either the first conductive impurity or the second conductive impurity is dominant by introducing an impurity whose conductive type is opposite to the impurity that was introduced in the first impurity introduction step into the polycrystalline semiconductor thin film so that the first layer faces the gate electrode; and
a third impurity introduction step of forming a source region and a drain region in which the conductive type of the introduced impurity becomes dominant by introducing an impurity whose conductive type is opposite to the impurity of the second layer by covering a portion of the semiconductor thin film with a mask.
